(19) United States
(12) Patent Application Publication
(10) Pub. No.: US 2026/0113877 A1
(43) Pub. Date: Apr. 23, 2026

(54) FILTRATION SYSTEM FOR A COOLANT DISTRIBUTION UNIT

(71) Applicant: LTI Holdings, Inc., Pleasanton, CA (US)

(72) Inventors: Sukhvinder Kang, Pleasanton, CA (US); John R. Durbin, Spotsylvania, VA (US); Bradley R. Whitney, Epsom, NH (US)

(21) Appl. No.: 19/361,783

(22) Filed: Oct. 17, 2025

Related U.S. Application Data
(60) Provisional application No. 63/709,247, filed on Oct. 18, 2024.
(60) Provisional application No. 63/709,224, filed on Oct. 18, 2024.

(51) Int. Cl. H05K 7/20; B01D 35/143; B01D 35/157

(52) U.S. Cl. CPC H05K 7/20272; B01D 35/143; B01D 35/1573; H05K 7/20763; B01D 2201/291

(57) ABSTRACT

A coolant distribution unit (CDU) includes a cabinet having walls, a door, a primary inlet, a primary outlet, a secondary inlet, and a secondary outlet. A heat exchanger assembly is positioned within the cabinet. A first flow path and second flow path extend from respective primary and second inlets, through a heat exchanger, to respective primary and secondary outlets. A first strainer is positioned between the primary inlet and the heat exchanger. The second flow path includes a second strainer, first and second pumps arranged in parallel, and first, second, and third filters arranged in parallel and downstream of the first and second pumps. A human-machine interface is mounted on the cabinet and a controller positioned in the cabinet electrically communicates with the human-machine interface, which are each electrically coupled to a power supply.

### CROSS-REFERENCE TO RELATED APPLICATIONS

This application claims priority to U.S. Provisional Patent Application No. 63/709,224, filed on Oct. 18, 2024, and to U.S. Provisional Patent Application No. 63/709,247, filed on Oct. 18, 2024, the entire contents of each of which is incorporated herein by reference.

### BACKGROUND

The present disclosure relates to filtration systems for coolant distribution units.

### SUMMARY

In some embodiments, the disclosure provides a coolant distribution unit that includes a cabinet having a plurality of walls, a door, a primary inlet, a primary outlet, a secondary inlet and a secondary outlet. A heat exchanger assembly is positioned within the cabinet. The heat exchanger assembly includes a heat exchanger, a first flow path and a second flow path. The first flow path extends from the primary inlet, through the heat exchanger and to the primary outlet. The first flow path includes a first strainer positioned between the primary inlet and the heat exchanger. The second flow path extends from the secondary inlet, through the heat exchanger to the secondary outlet. The second flow path includes a second strainer, first and second pumps arranged in parallel, and first, second and third filters arranged in parallel and downstream of the first and second pumps. A human-machine interface is mounted on the cabinet. A controller is positioned in the cabinet and in electrical communication with the human-machine interface. A power supply is electrically connected to the human-machine interface and the controller.

In some embodiments, the disclosure provides a coolant distribution unit including: a cabinet supporting a primary inlet, a primary outlet, a secondary inlet and a secondary outlet; a heat exchanger assembly positioned within the cabinet, the heat exchanger assembly including a heat exchanger, a first flow path extending from the primary inlet, through the heat exchanger and to the primary outlet, the first flow path including a first strainer positioned between the primary inlet and the heat exchanger, and a second flow path extending from the secondary inlet, through the heat exchanger to the secondary outlet, the second flow path including a second strainer, one or more pumps, and one or more filters arranged in parallel and downstream of the one or more pumps; a fill branch fluidly communicating the second flow path.

In some embodiments, the disclosure provides a coolant distribution unit including: a cabinet supporting a primary inlet, a primary outlet, a secondary inlet and a secondary outlet; a heat exchanger assembly positioned at least partially within the cabinet, the heat exchanger assembly including a heat exchanger, a first flow path extending from the primary inlet, through the heat exchanger and to the primary outlet, the first flow path including a first strainer positioned between the primary inlet and the heat exchanger, and a second flow path extending from the secondary inlet, through the heat exchanger to the secondary outlet, the second flow path including a second strainer, one or more pumps, and one or more filters arranged downstream of the one or more pumps; wherein a ratio of the filters to the pumps is greater than 1:1.

In some embodiments, the first, second and third filters each include a shut off valve and an air vent, so that one of the respective filters can be isolated and then replaced while the coolant distribution unit is in operation.

In some embodiments, a first manifold is positioned between the first and second pumps and the first, second and third filters, and a second manifold positioned downstream of the first, second and third filters. In these embodiments, fluid flows in parallel through the first and second pumps into the first manifold, then the fluid flows in parallel through the first, second and third filters and into the second manifold.

In some embodiments, the first flow path further includes a first removable filter upstream of the heat exchanger. The first removable filter is removed after a set time period has elapsed or after a signal from the controller indicates that the first removable filter should be removed.

In some embodiments, the first flow path includes a bypass passage and a valve that can permit fluid to bypass the first strainer.

In some embodiments, the second flow path includes a bypass passage and a valve that can permit fluid to bypass the second strainer.

Other aspects of the disclosure will become apparent by consideration of the detailed description and accompanying drawings.

### BRIEF DESCRIPTION OF THE DRAWINGS

FIG. 1 is a perspective view of a coolant distribution unit.

FIG. 2 is a front perspective view of the coolant distribution unit with the wall panels and doors removed.

FIG. 3 is a rear perspective view of the coolant distribution unit with the wall panels and doors removed.

FIG. 4 is a rear view of the coolant distribution unit with the wall panels removed.

FIG. 5 is a side view of the coolant distribution unit with the wall panels removed.

FIG. 6A is a schematic view of a heat exchange assembly of the coolant distribution unit.

FIG. 6B is a schematic view of a heat exchanger assembly of the coolant distribution unit.

FIG. 7 is a perspective view of a filter assembly of the coolant distribution unit.

FIG. 8 is a section view of a joint of the coolant distribution unit.

FIG. 9 is a schematic view of a coolant storage unit and a fill wand.

FIG. 10 is a perspective view of a portion of a coolant distribution unit and a fill wand.

### DETAILED DESCRIPTION

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways.

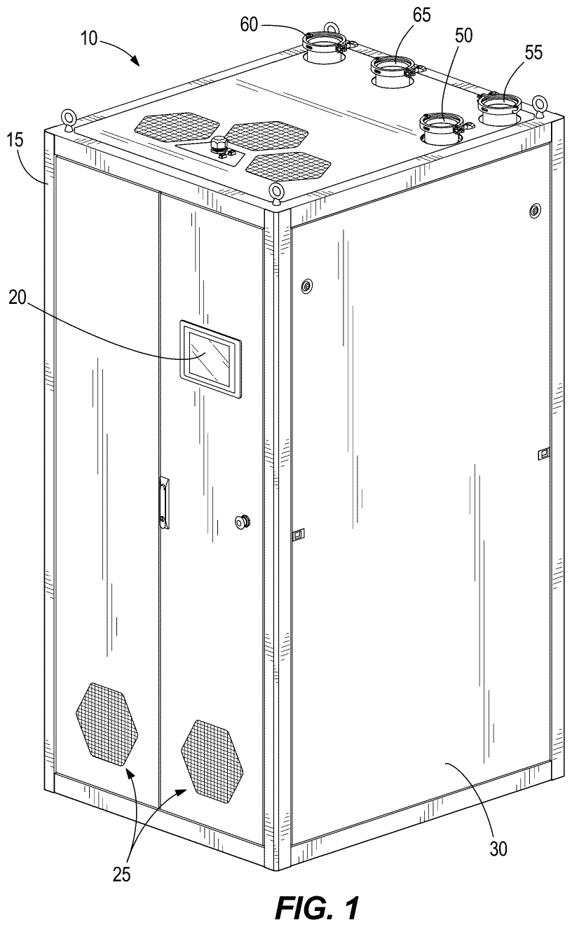

FIG. 1 illustrates a coolant distribution unit 10 that is configured to distribute coolant to one or more servers, processors or other high heat components. The illustrated coolant distribution unit 10 includes a cabinet 15 and a human-machine interface (HMI) 20. The cabinet 15 includes doors 25 and wall panels 30 that contain the components of the coolant distribution unit 10. The doors 25 are openable by an operator to access the components inside the cabinet 15. The illustrated HMI 20 includes a touch screen, but other embodiments include one or more keypads and/or screens to permit a user to interact with the coolant distribution unit 10.

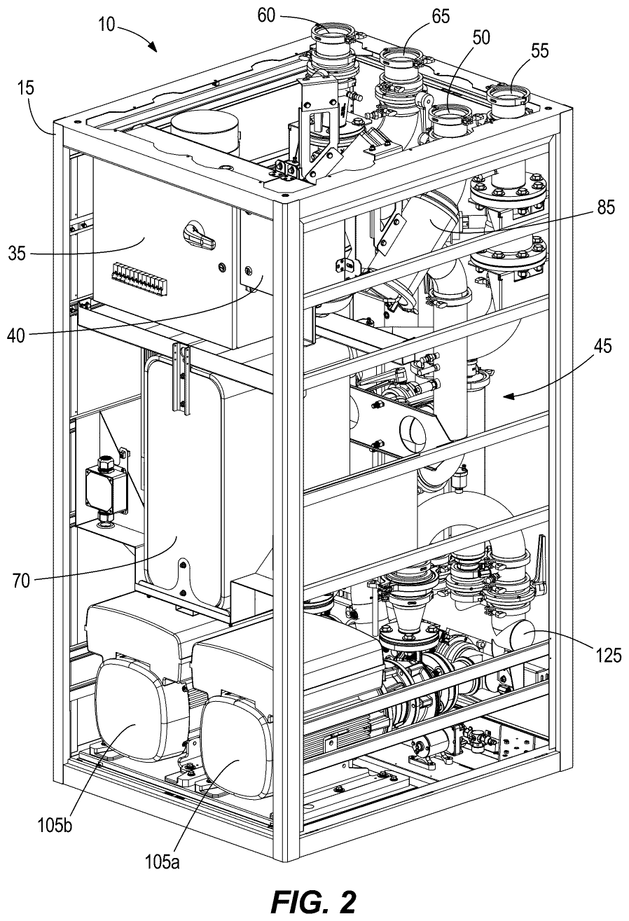

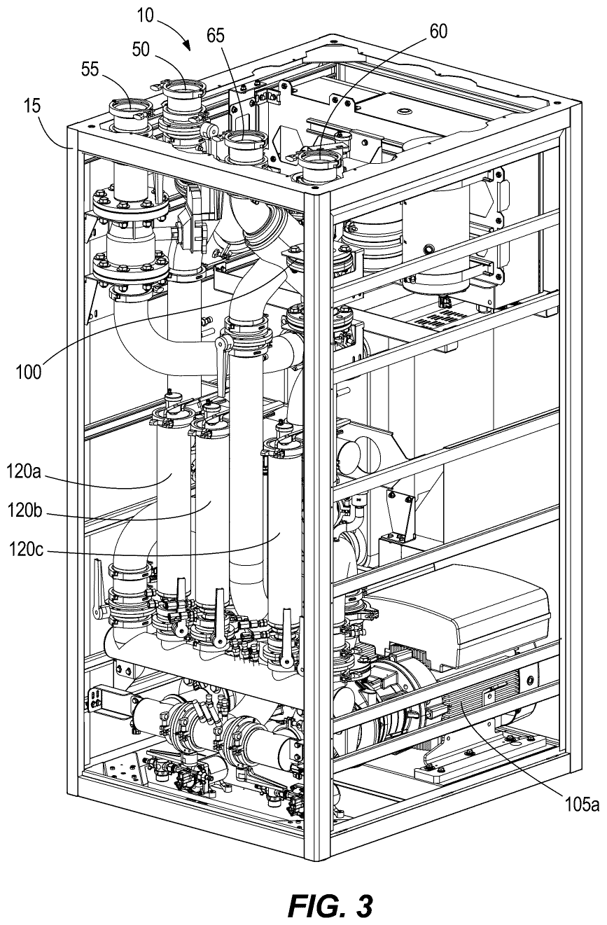

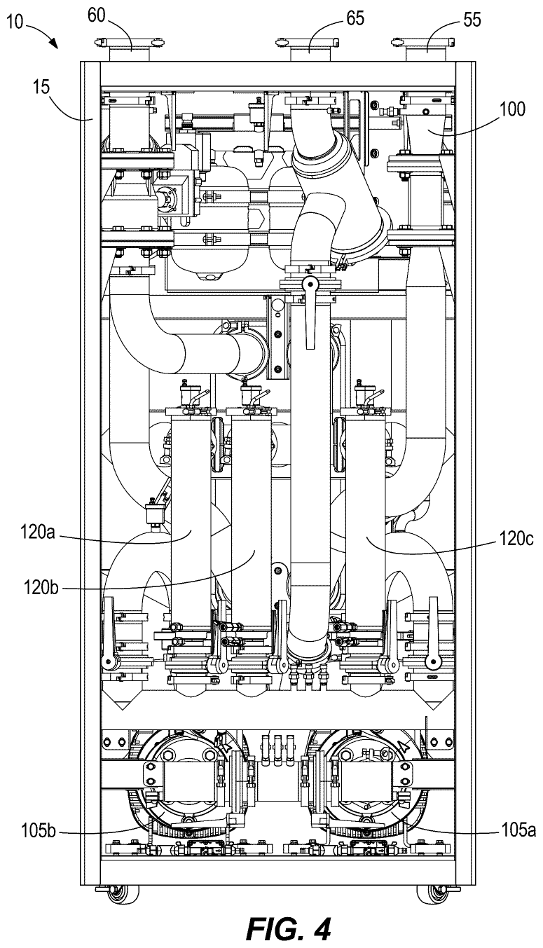

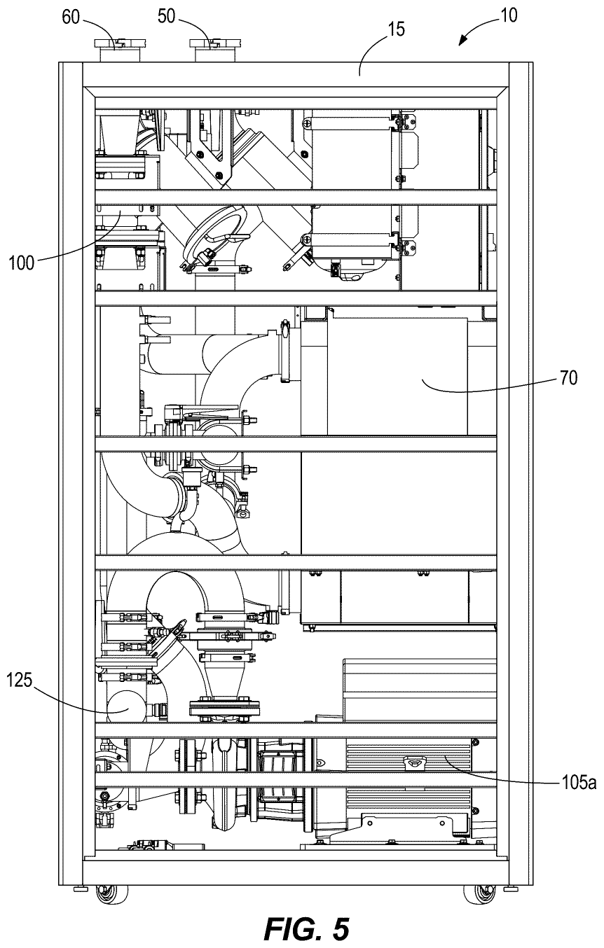

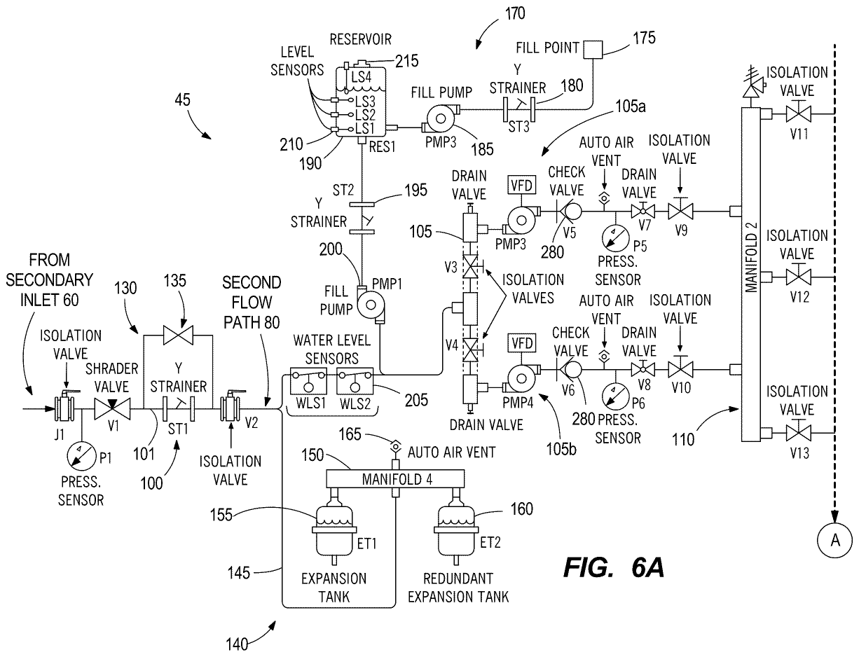

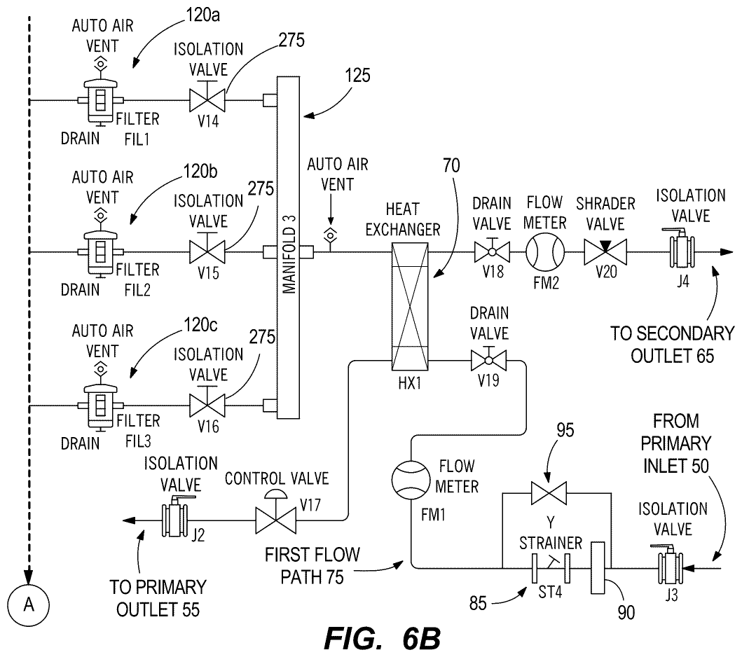

FIGS. 2-5 illustrate the coolant distribution unit 10 with the doors 25 and wall panels 30 removed for clarity. The coolant distribution unit 10 includes a power supply 35, a controller 40, a heat exchange assembly 45, a primary inlet 50, a primary outlet 55, a secondary outlet 60 and a secondary inlet 65. The power supply 35 connects to a power source (i.e., an electrical outlet and/or a battery) and selectively directs power to various components within the coolant distribution unit 10, such as valves, sensors, pumps, etc. The controller 40 is electrically connected to the HMI 20, the power supply 35 and other components within the coolant distribution unit 10, such as valves, sensors, pumps, etc. FIGS. 6A and 6B are a schematic that illustrates the heat exchange assembly 45. The heat exchange assembly 45 includes a heat exchanger 70, a first flow path 75 and a second flow path 80. The heat exchanger 70 is configured to permit a first fluid flowing along the first flow path to remove heat from (i.e., reduce the temperature of) a second fluid flowing along the second flow path.

The first flow path 75 extends from the primary inlet 50, through the heat exchanger 70 and then to the primary outlet 55. The fluid flowing from the primary outlet 55 is directed into a building cooling system, such as a roof-mounted heat exchanger. The building cooling system cools the first fluid and then directs the cooled first fluid into the primary inlet 50. The first fluid is then heated by the second fluid in the heat exchanger 70. When the first fluid exits the primary outlet 55, the first fluid is returned to the building cooling system to be cooled again.

The second flow path 80 extends from the secondary inlet 65, through the heat exchanger 70 and then to the secondary outlet 60. After exiting the secondary outlet 60, the second fluid is directed into one or more servers and/or other data center components to absorb heat and thus cool the one or more servers and/or other data center components. After the second fluid has absorbed heat from the one or more servers and/or other components, the second fluid is directed into the secondary inlet 65. Then, the second fluid is cooled by the first fluid in the heat exchanger 70. When the cooled second fluid exits the secondary outlet 60, the second fluid is returned to the one or more servers and/or other data center components to be heated again.

The first flow path 75 includes a first strainer 85 and a first removable filter 90 upstream of the heat exchanger 70 and one or more pumps through which the first fluid flows. The illustrated first strainer 85 and first removable filter 90 are configured to filter out particles from the first fluid upstream of the heat exchanger 70. In some embodiments, a bypass path 95 selectively permits fluid to bypass the first strainer 85 and the first removable filter 90. In some embodiments, the first removable filter 90 is positioned within the first strainer 85. In these embodiments, the first removable filter 90 can be removed from the first strainer 85 and replaced with a different screen and/or filter. In some embodiments, the replacement screen and/or filter can filter out finer particles than the first removable filter 90. In some embodiments, the first removable filter 90 is positioned in series with a finer screen and/or filter. The finer screen and/or filter can remain in place while the first removable filter 90 is removed. The first removable filter 90 is utilized for a time period after the coolant distribution unit 10 has been installed and activated, and then removed after the time period has elapsed. In some embodiments, the first removable filter 90 remains in place until a sensor indicates that the first fluid has reached the desired level of filtration. The first removable filter 90 provides an added benefit of cleaning the fluid that flows through the building cooling system, as well as removing any debris accrued in the coolant distribution unit 10 during manufacturing, shipping and installation.

The illustrated second flow path 80 includes a second strainer 100, first and second pumps 105a, 105b, a first manifold 110, a plurality of filters 120a, 120b, 120c and a second manifold 125 upstream of the heat exchanger 70. The second strainer 100 filters out particles upstream of the first and second pumps 105a, 105b. The particles filtered out by the second strainer 100 include particles generated during manufacturing, transport and installation, as well as any particles accrued by the one or more servers and/or other data center components. In some embodiments, the second strainer 100 can be omitted. In some embodiments, a bypass passage 130 and valve 135 selectively permit fluid to bypass the second strainer 100. In some embodiments, the valve 135 is shut until a sensor indicates that the second fluid has reached the desired level of filtration. In other embodiments, the valve 135 is shut for a set period of time after the coolant distribution unit 10 is activated. After the appropriate signal from the sensor or the set time period has elapsed, the controller 40 sends a signal to open the valve 135 so that the second strainer 100 can be bypassed.

In the illustrated embodiment, the first and second pumps 105a, 105b are in parallel and propel fluid into the first manifold 110. In the illustrated embodiment, there are three filters 120a, 120b, 120c in parallel that receive fluid from the first manifold 110 and direct fluid into the second manifold 125. Each filter 120a, 120b, 120c includes a dedicated shut off valve and an air vent. The filters can be isolated and replaced one at a time while the coolant distribution unit 10 is in operation. There are more filters than pumps, so the ratio of filters to pumps is greater than 1:1 (i.e., 3:2 or 1.5:1). While the shut off valve to one of the filters (120a for example) is closed to permit the respective filter to be replaced, fluid flows through the other two of the filters (120b, 120c for example) so that the system operates at a ratio of 1:1 filters to pumps. This permits the desired system performance to be maintained while replacing one of the filters 120a, 120b, 120c. When one of the filters is isolated, the other two filters provide about 66% of the total filter area, so performance is maintained. In some embodiments, a single pump can be utilized in place of the first and second pumps 105a, 105b. The single pump would move fluid through all three filters 120a, 120b, 120c unless one is taken offline to be serviced or replaced. While one of the filters is offline, the single pump would move fluid through the other two filters.

The secondary cooling loop 80 includes an expansion tank branch 140. The expansion tank branch 140 includes an expansion line 145 coupled to a tank manifold 150 to which a first expansion tank 155 and a second, redundant expansion tank 160 are fluidly coupled. Excess coolant in the secondary cooling loop 80 can flow into or out of the expansion tanks 155, 160 depending on the conditions of the CDU 10 (e.g., expansion of secondary coolant based on heat transferred to the secondary coolant by servers, offline/underutilized status of servers, etc.). The tank manifold 150 includes an air vent 165.

The secondary cooling loop 80 further includes a fill branch 170 in fluid communication with the secondary cooling loop 80. The fill branch 170 includes a fill port 175, a strainer 180, a first pump 185, a reservoir 190, a second strainer 195, and a second pump 200 coupled to the secondary inlet line 101 of the secondary cooling loop 80, for instance, between the level sensors 205 and a pump manifold 105. The first and second pumps 185, 200 generate a flow of secondary coolant from the fill port 175 through the first strainer and into the reservoir 190, and from the reservoir 190 through the second strainer 195 to the pump manifold 105. The strainers 180, 195 filter out larger diameter particles that may be present in the secondary coolant. The reservoir 190 includes level sensors 210 and a breather 215. The reservoir 190 may be filled with the secondary coolant as a service fluid containment option, in which the second pump 200 may be operable in a reverse direction to pump the secondary coolant from the secondary cooling loop 80 into the reservoir 190 to remove the secondary coolant from a section of the secondary cooling loop 80 to complete service of a filter assembly, pump assembly, etc. It will be appreciated that by recovering the secondary coolant from the secondary cooling loop 80, the secondary coolant may be conserved for further use, while lowing the risk of introducing additional contamination.

With reference to FIG. 7, each of the filters 120a, 120b, 120c (120a shown) includes include an outer shell 220 that supports and at least partially encloses a filter medium (not shown) coupled to an end cap 225 that is clamped within the outer shell 220 by a clamp 230. A handle 235 extends from the end cap 225 for ease in handling the filter medium for removal and replacement. The end cap 225 include an air vent 240 and the outer shell 220 includes drain ports 245 to allow the secondary coolant to be drained from the filter medium and outer shell 220 prior to servicing to reduce the amount of secondary coolant lost during a filter service operation (e.g., a filter replacement).

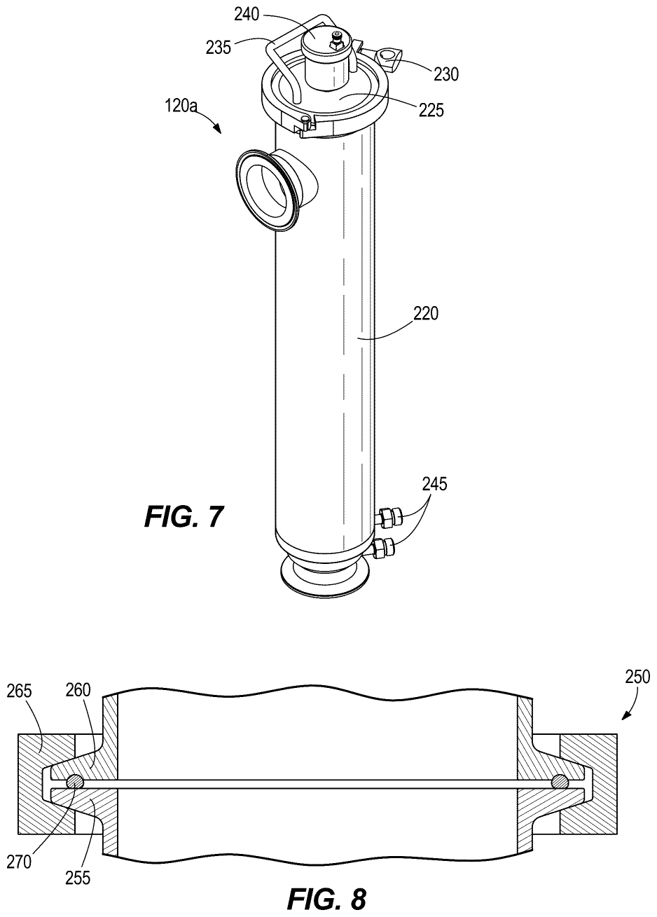

With reference to FIG. 8, the heat exchanger assembly 45 includes one or more joints formed as modular joints 250 between pipe segments and/or other components of the system (pumps, filter housings, heat exchangers, etc.). The modular joints 250 include flanged ends 255, 260 (coupled by a clamp 265 or fasteners in other embodiments) and a seal 270 (e.g., an O-ring, gasket, etc.) positioned between the flanged ends 255, 260. In the present embodiment, the following joints are formed as modular joints: the joints between the outer shells 220 of the filters 120a, 120b, 120c and the isolation valves 275, the upstream and downstream joints of the strainer 85, and the joints between the first and second pumps 105a, 105b and the downstream check valves 280. It will be appreciated that by using a modular joint in place of a welded joint, components upstream or downstream of the modular joint may be more easily serviced or removed, if no longer needed/desired in the CDU 10 allowing more flexibility in configuration for different use cases, for more easy assembly, or other reasons.

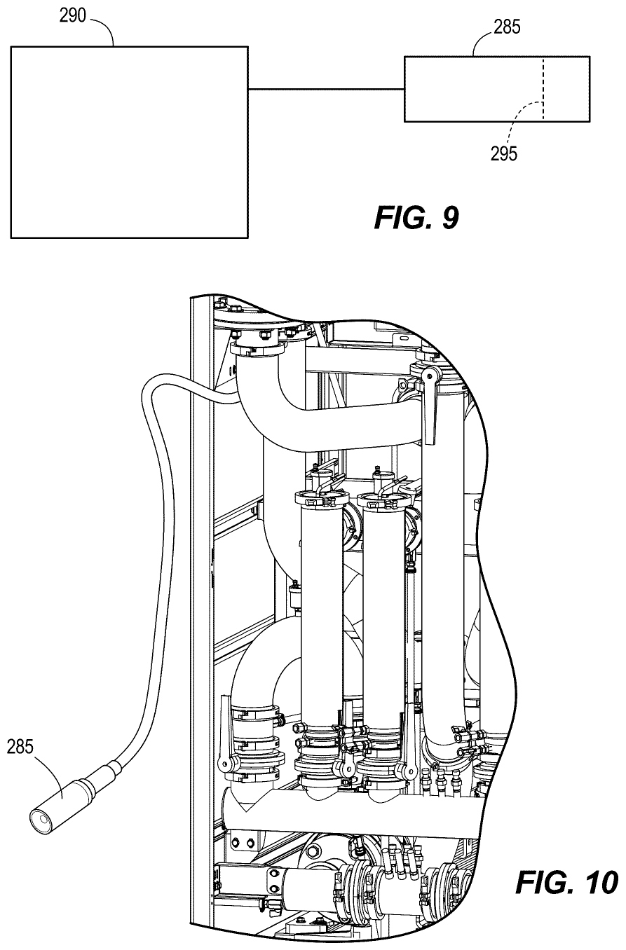

With reference to FIGS. 9 and 10, following assembly and pre-shipping testing of the CDU 10, the CDU is filled with a quantity of secondary coolant, and then again during installation at a facility, the CDU 10 may be filled with additional secondary coolant to adequately cool a remote location in the facility (e.g., servers located in an area remote from the CDU). Secondary coolant is added to the CDU 10 via the fill port 175 using a fill wand 285 coupled to the fill port 175 and fluidly coupled to a coolant storage unit 290. Coolant may be added, for instance, during start up or service. The fill wand 285 includes a filter 295 (e.g., a large particle strainer that prevents larger diameter particles from entering the CDU 10.

Various filtration configurations are disclosed herein that enhance the operation of the coolant distribution unit 10.

What is claimed is:

1. A coolant distribution unit comprising:
a cabinet having a plurality of walls, a door, a primary inlet, a primary outlet, a secondary inlet and a secondary outlet;
a heat exchanger assembly positioned within the cabinet, the heat exchanger assembly including
a heat exchanger,
a first flow path extending from the primary inlet, through the heat exchanger and to the primary outlet, the first flow path including a first strainer positioned between the primary inlet and the heat exchanger, and
a second flow path extending from the secondary inlet, through the heat exchanger to the secondary outlet, the second flow path including a second strainer, first and second pumps arranged in parallel, and first, second and third filters arranged in parallel and downstream of the first and second pumps;
a human-machine interface mounted on the cabinet;
a controller positioned in the cabinet and in electrical communication with the human-machine interface; and
a power supply electrically coupled to the human-machine interface and the controller.

2. The coolant distribution unit of claim 1, wherein the first, second and third filters each include a shut off valve and an air vent, such that one of the respective filters can be isolated and then replaced while the coolant distribution unit is in operation.

3. The coolant distribution unit of claim 2, further comprising a first manifold positioned between the first and second pumps and the first, second and third filters, and a second manifold positioned downstream of the first, second and third filters, such that fluid flows in parallel through the first and second pumps into the first manifold, then the fluid flows in parallel through the first, second and third filters and into the second manifold.

4. The coolant distribution unit of claim 2, wherein a ratio of filters to pumps is greater than 1:1.

5. The coolant distribution unit of claim 1, wherein the first flow path further includes a first removable filter upstream of the heat exchanger, the first removable filter configured to be removed after a set time period has elapsed or after a signal from the controller indicates that the first removable filter should be removed.

6. The coolant distribution unit of claim 4, wherein the first flow path further includes a bypass passage and a valve configured to selectively permit fluid to bypass the first strainer.

7. The coolant distribution unit of claim 1, wherein the second flow path further includes a bypass passage and a valve configured to selectively permit fluid to bypass the second strainer.

8. A coolant distribution unit comprising:
a cabinet supporting a primary inlet, a primary outlet, a secondary inlet and a secondary outlet; and
a heat exchanger assembly positioned within the cabinet, the heat exchanger assembly including
a heat exchanger,
a first flow path extending from the primary inlet, through the heat exchanger and to the primary outlet, the first flow path including a first strainer positioned between the primary inlet and the heat exchanger, and
a second flow path extending from the secondary inlet, through the heat exchanger to the secondary outlet, the second flow path including a second strainer, one or more pumps, and one or more filters arranged in parallel and downstream of the one or more pumps;
a fill branch fluidly communicating the second flow path.

9. The coolant distribution unit of claim 8, wherein the one or more pumps includes a first pump and a second pump, and the one or more filters includes a first filter, a second filter, and a third filter.

10. The coolant distribution unit of claim 8, wherein the heat exchanger assembly includes a plurality of pipe segments defining the first flow path and the second flow path, and fluidly communicating the heat exchanger, the first strainer, the second strainer, the one or more pumps, and the one or more filters, a plurality of joints are defined between the plurality of pipe segments and at least the first strainer, the second strainer, the one or more pumps, and the one or more filters, wherein one or more of the joints is a modular joint.

11. The coolant distribution unit of claim 10, wherein the modular joint includes a first flange and a second flange, a seal positioned between the first flange and the second flange, and a clamp coupling the first flange and the second flange.

12. The coolant distribution unit of claim 8, wherein the one or more filters includes an outer shell that receives a filter medium, an end cap coupled to the outer shell and enclosing the filter medium.

13. The coolant distribution unit of claim 12, wherein a handle extends from the end cap.

14. The coolant distribution unit of claim 12, wherein an air vent is coupled to the end cap.

15. The coolant distribution unit of claim 12, wherein the outer shell supports a drain valve.

16. The coolant distribution unit of claim 8, further comprising an expansion tank branch fluidly coupled to the second flow path, the expansion tank branch including an expansion tank configured to receive an excess quantity of fluid from the second flow path.

17. The coolant distribution unit of claim 8, wherein a fill wand is couplable to a fill portion of the fill branch to receive a coolant from a coolant storage unit.

18. The coolant distribution unit of claim 17, wherein the fill wand includes a filter.

19. The coolant distribution unit of claim 8, wherein the one or more filters includes at least a first filter and a second filter, the first filter and the second filter configured to maintain a filtration performance when either the first filter or the second filter is bypassed.

20. A coolant distribution unit comprising:
a cabinet supporting a primary inlet, a primary outlet, a secondary inlet and a secondary outlet; and
a heat exchanger assembly positioned at least partially within the cabinet, the heat exchanger assembly including
a heat exchanger,
a first flow path extending from the primary inlet, through the heat exchanger and to the primary outlet, the first flow path including a first strainer positioned between the primary inlet and the heat exchanger, and
a second flow path extending from the secondary inlet, through the heat exchanger to the secondary outlet, the second flow path including a second strainer, one or more pumps, and one or more filters arranged downstream of the one or more pumps;
wherein a ratio of the filters to the pumps is greater than 1:1.
